(19) United States
(12) Patent Application Publication
(10) Pub. No.: US 2015/0191846 A1
(43) Pub. Date: Jul. 9, 2015

(54) SYSTEM AND METHOD OF GROWING SILICON INGOTS FROM SEEDS IN A CRUCIBLE AND MANUFACTURE OF SEEDS USED THEREIN

(71) Applicant: GTAT Corporation, Merrimack, NH (US)

(72) Inventors: Ian T. Witting, Goffstown, NH (US); Vikram Singh, Andover, MA (US); Ning Duanmu, Nashua, NH (US)

(21) Appl. No.: 14/422,077

(22) PCT Filed: Aug. 16, 2013
(86) PCT No.: PCT/US2013/055323

§ 371 Date: Feb. 17, 2015

Related U.S. Application Data
(60) Provisional application No. 61/684,331, filed on Aug. 17, 2012.

(51) Int. Cl. C30B 11/14; C30B 29/06; C30B 11/02

(52) U.S. Cl. CPC C30B 11/14; C30B 11/02; C30B 29/06

(57) ABSTRACT

Systems and methods that reduce the overall cost of producing a silicon ingot are provided herein. More specifically, one or more surface pieces may be sliced from a silicon boule in relation to a plurality of nodes at a particular orientation. These one or more surface pieces may then be formed into one or more seeds having a specific length, width and thickness usable in a silicon ingot growth process. By utilizing these pieces to form one or more seeds, pieces of a boule which would have been previously discarded may now be used to form high quality seeds for use in a silicon ingot grow process.

### CROSS-REFERENCE TO RELATED APPLICATION

This application claims the benefit of U.S. Provisional Patent Application Ser. No. 61/684,331, filed Aug. 17, 2013. The entire contents of this application are hereby incorporated by reference herein.

### FIELD OF THE INVENTION

The present invention relates to a system and method of growing silicon ingots from seeds in a crucible, and the method of manufacturing the seeds used therein.

### BACKGROUND

Crystal growth apparatuses or furnaces, such as directional solidification systems (DSS), involve the melting and controlled resolidification of a feedstock material, such as silicon, in a crucible to produce an ingot. Production of a solidified ingot from molten feedstock occurs in several identifiable steps over many hours. For example, to produce a silicon ingot by the DSS method, solid silicon feedstock is loaded into a crucible and placed into the hot zone of a DSS furnace. The feedstock charge is then heated using various heating elements within the hot zone to form a liquid feedstock melt, and the furnace temperature, which is well above the silicon melting temperature of 1412° C., is maintained for several hours to ensure complete melting. Once fully melted, heat is removed from the melted feedstock, often by applying a temperature gradient in the hot zone, in order to directionally solidify the melt and form a silicon ingot. By controlling how the melt solidifies, an ingot having greater purity than the starting feedstock material can be achieved, which can then be used in a variety of high end applications, such as in the semiconductor and photovoltaic industries.

For the preparation of a monocrystalline silicon ingot using a DSS process, single crystal seed tiles (seeds) are typically placed in a layer at the bottom of the crucible that is being used for the production of silicon ingots. The silicon feedstock is then loaded on top of the seeds and melted from top down. Once the melt reaches the top of the seeds, the process transitions to a directional solidification stage. The seeds remain at least partially solid throughout the process and serve as a template for the crystallization of the melted feedstock. That is, although the surface of the seeds may partially melt, since the growth (solidification of the melt) starts at the surface of the seeds, the crystalline structure of the seeds is replicated throughout the resulting grown ingot.

These seeds typically range in thickness from about 5 mm to 35 mm and cover a significant area of the crucible bottom, usually the entire bottom of the crucible. The dimensions of a standard crucible can be quite large and thus, a significant number of seeds are required in order to grow the above described silicon ingots.

Since the cost of the seeds required are typically quite high (e.g., about $2,000 to $10,000 per ingot), the manufacturing costs of each individual ingot are extremely high as well as a result. Therefore, there is a need for a system and method of producing silicon ingots that reduces the manufacturing costs of each ingot and simplifies the orientation process to produce a higher quality ingot at a lower cost.

### SUMMARY

Systems and methods to reduce the overall cost of producing a silicon ingot are provided herein. More specifically, one or more surface pieces may be sliced from a silicon boule in relation to a plurality of nodes at a particular orientation. These one or more surface pieces may then be formed into one or more seeds having a specific length, width and thickness usable in a silicon ingot growth process. By utilizing these pieces to form one or more seeds, pieces of a boule which would have been previously discarded may now be used to form high quality seeds for use in a silicon ingot growth process.

Preferably, the surface pieces may be one or more residual pieces that are a direct result of a process for squaring a silicon boule into a brick. These surface pieces may then be arranged in a bottom of a crucible in various orientations.

In some exemplary embodiments of the present invention, the surface pieces may also be cropped by cutting each surface piece a plurality of times. The cropped surface pieces may then be sliced into a plurality of seeds and placed in the bottom of the crucible. The seed or seeds may then be placed in the crucible in a particular orientation which is configured to prevent or reduce the formation and spread of subgrain boundaries within the grown ingot.

Other aspects and embodiments of the invention are discussed below.

### BRIEF DESCRIPTION OF THE DRAWINGS

For a better understanding of the nature and desired objects of the present invention, reference is made to the following detailed description taken in conjunction with the accompanying drawing figures wherein like reference character denote corresponding parts throughout the several views and wherein:

FIG. 1 is a prospective view of an exemplary surface piece from a boule according to an exemplary embodiment of the present invention;

FIG. 2 is a cross-sectional view of a resulting brick and residual pieces after a boule has been squared according to an exemplary embodiment of the present invention;

FIG. 3 depicts a first exemplary seed orientation for seeds to be placed in a crystal growth apparatus in accordance with an exemplary embodiment of the present invention;

FIGS. 4A-D depict a cropping technique and a second exemplary seed orientation for seeds to be placed in a crystal growth apparatus in accordance with an exemplary embodiment of the present invention;

FIGS. 5A-D depict a cropping technique and a third exemplary seed orientation for seeds to be placed in a crystal growth apparatus in accordance with an exemplary embodiment of the present invention;

FIGS. 6A-D depict a cropping technique and a fourth exemplary seed orientation for seeds to be placed in a crystal growth apparatus in accordance with an exemplary embodiment of the present invention;

FIGS. 7A-E depict yet another exemplary cropping technique that may be used in relation to seed orientation shown in FIG. 7E according to the exemplary embodiment of the present invention;

FIG. 8 is a minority carrier lifetime scan of a brick face and the resulting boundary between two seeds which are oriented according to the seed orientation shown in FIG. 7E;

FIG. 9 is a flowchart illustrating a method for growing silicon ingot in a crystal growth apparatus according to the seed manufacturing technique of the exemplary embodiment of the present invention; and

FIG. 10 is a cross-sectional front view of an exemplary crystal growth apparatus which may be used to grow silicon ingots according to the exemplary embodiments of the present invention.

### DEFINITIONS

The instant invention is most clearly understood with reference to the following definitions:

As used in the specification and claims, the singular form “a”, “an” and “the” include plural references unless the context clearly dictates otherwise.

A “crystal growth apparatus” as described herein refers to any device or apparatus capable of heating and melting a solid feedstock, such as silicon, at temperatures generally greater than about 1000° C. and subsequently promoting resolidification of the resulting melted feedstock material to form a crystalline material, such as a monocrystalline silicon ingot, for photovoltaic (PV) and/or semiconductor applications.

A “cropping device” as described herein is any device that is capable of precisely cutting silicon into one or more pieces. A cropping device may be for example a knife, an automated saw, or any other specifically configured device known in the art for effecting precise cutting techniques.

A “squaring device” as described herein is any device that is capable of precisely squaring silicon into one or more pieces having a square cross sectional shape, such as a brick. A squaring device may be for example an automated computer-aided manufacturing machine or a saw that is specifically configured to square silicon boules.

A “surface piece” as described herein is a semi-cylindrical piece that is sliced from a cylindrical boule, sometimes referred to as a cylindrical segment. These surface pieces include at least one surface that originated as a portion of the surface of the original cylindrical boule before the boule was cut, sliced, or in some instances even sectioned. These surface pieces preferably are residual pieces that are a result of squaring a boule during a typical squaring process. However, residual pieces may also be removed from the boule on an individual basis before or after the boule has been sectioned. Accordingly, the illustrative embodiments of the present invention are not limited as such.

### DETAILED DESCRIPTION

Preferred embodiments of the subject invention are described below with reference to the accompanying drawings, in which like reference numerals represent the same or similar elements.

The subject invention relates to systems and methods of growing silicon ingots in a crucible of a directional solidification process. As stated above, single crystal seed tiles (seeds) are placed in a layer at the bottom of a crucible (e.g., a casting crucible) that is being used for the production of silicon ingots. The silicon feedstock is then loaded on top of the seed(s) and melted from top down. Once the melt reaches the top of the seeds, the process transitions to a directional solidification stage. Most of the bulk of the seeds remain solid (or mostly solid) throughout the casting process and serve as a template for the crystallization of the melted feedstock. Since the growth (solidification of the melt) starts at the surface of the seed, the crystalline structure of the seed is replicated throughout the resulting ingot.

Currently the total cost of just the seeds for producing one ingot of monocrystalline silicon through the above process is in the order of $2000-$10000/ingot. This cost is substantially due to the value of the material from which the seeds are prepared. In particular, seeds are cut from bricks from which wafers would have been sliced. Thus, a process which reduces the overall cost of each individual ingot by reducing the cost of the seeds while at the same time taking into consideration sub-grain boundary formations would be extremely beneficial to the industry as a whole.

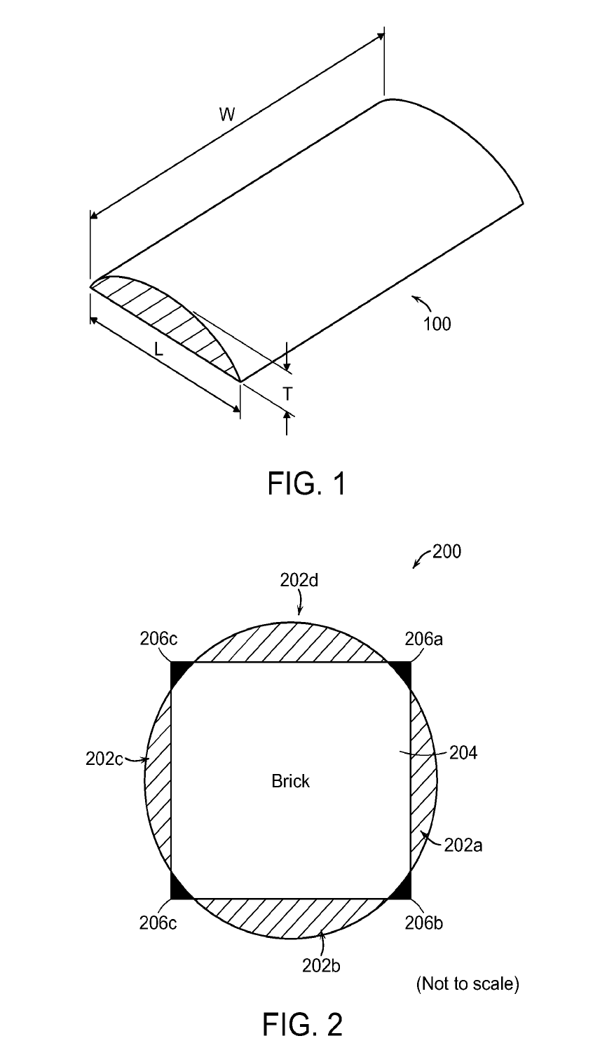

The exemplary embodiment of the present invention includes systems and methods for reducing the overall cost of producing a silicon ingot by reducing the cost of the seeds used in growing the ingot. More specifically, costs associated with silicon ingot growth manufacturing are reduced by utilizing one or more surface pieces that are sliced from a boule. These surface pieces may be residual pieces that are a result of squaring a boule during a silicon brick manufacturing process or alternatively may be individually sliced from any one of four sides of cylindrical silicon boule in relation to a plurality of nodes at a particular orientation on the boule. As noted above, since the surface pieces include the a segment of the surface of a cylinder, each piece should have a one curved surface and thee flat surfaces when they are originally sliced from the boule. For example, FIG. 1 depicts an exemplary surface piece 100 that has been sliced from one of the side surfaces of the cylindrical boule.

For example, a boule formed using the Czochralski (Cz) process contains an upper “neck” section and bottom “tail” section, which is generally sectioned or removed to form a relatively cylindrical boule having a desired or target length. The resulting cylindrical boule is then typically further processed by slicing off the rounded sides to form a brick having a square or pseudo-square cross sectional shape (often referred to as squaring), which can then be further sliced into wafers for use in a solar cell. This is illustrated in FIG. 2, where boule 200 is squared by removing residual pieces 202a-d, sometimes referred to as “wings,” forming brick 204. As a result, surface pieces (such as the four residual pieces 202a-d), shown in FIG. 1, are flat on one surface (i.e., the cut surface) and also have a curved outer surface due to the cylindrical shape of boule 200. The resulting residual pieces are formed due to squaring the boule 200 into, preferably, a square or pseudo-square shape in relation to a plurality of nodes 206a-d projecting out from the boule at a particular disposition. As mentioned above, the boule 200 may be a silicon boule formed by a Czochralski growth process or a float zone growth process, however, the illustrative embodiment of the present invention is not limited thereto. Furthermore, although the surface pieces discussed in the detailed description of the embodiments below are referred to as being obtained from the above squaring process, the illustrative embodiment of the present invention is not necessarily limited thereto.

Conventionally, the surface pieces (especially residual pieces resulting from squaring a boule) are broken into smaller pieces by the brick manufactures and recycled for use as feedstock either in CZ or directional solidification system (DSS) growth processes. Advantageously, however, the exemplary embodiment of the present invention utilizes these surface/residual pieces, which are considered waste and are therefore inexpensive, in order to manufacture at least one seed for use in a silicon ingot growth process, thereby reducing the overall costs associated with ingot manufacture.

Alternatively, as mentioned above, these surface pieces may be individually sliced from the cylindrical silicon boule as part of an intentional process to obtain a surface piece 204 that is not a result of the squaring process discussed above. Accordingly, the illustrative embodiment of the present invention is not limited to surface pieces that are obtained only from a squaring process, as the squaring process is merely a preferable method of obtaining the surface pieces that would normally be discarded.

Regardless of whether the surface pieces are residual pieces resulting from squaring or individual surface pieces that are intentionally sliced from the boule, the slice should be made in relation to at least two nodes at a particular orientation on the boule. That is, the slicing planes should be made with consideration of the orientation of the crystal (i.e., due to the relationship with the plurality of nodes) within the boule. For example, with a silicon boule, doing so insures that the surface pieces themselves preferably have a <100> orientation in the vertical direction when placed with the flat surface facing downward. The surface pieces also preferably have a <100> orientation along the length of any one surface piece as this is parallel to the growth orientation of the boule. This also implies that a direction normal to the first two directions (i.e., the vertical direction and the direction along the length of the residual piece) also has a <100> family plane due to the cubic symmetry of a silicon crystal lattice.

That is, in the exemplary embodiment of the present invention, when a silicon boule is squared in relation to a plurality of specifically identified nodes located on the outer surface of the boule, a vector drawn normal from the axis of growth through any node is a <110> direction. Thus, by squaring the boule in relation to these nodes, a proper surface orientation of the resulting brick can be assumed. Therefore, a <100> orientation may be obtained along the side surface of a pseudo square brick as well as along the flat surfaces of the residual pieces.

In the above exemplary embodiment of the present invention, the boule should preferably have a diameter of about 170 mm-220 mm and more preferably has a diameter of about 205 mm. The resulting silicon brick preferably has a square or pseudo square cross sectional shape having sides of about 150 mm-170 mm and preferably 150-155 mm. Preferably the length of the brick is between about 350 mm-450 mm and more preferably between about 375-425 mm, such as about 400 mm. Each surface piece may have a width W that is similar to that of the resulting brick (e.g., preferably 90 mm-105 mm, and more preferably 95-100 mm) and a thickness (from the flat surface to the curved surface) from about 0.1 mm-24 mm). Alternatively, each of the surface pieces may be sectioned into a plurality of surface pieces that are each smaller than the cylindrical boule from which they were sliced.

In the exemplary embodiment of the present invention a crystal growth apparatus configured to promote monocrystalline growth by directional solidification may be provided and at least one seed and a feedstock material are preferably placed in a crucible in the crystal growth apparatus. The crystal growth apparatus is then heated to melt the feedstock material, preferably without substantially melting the seed(s), contained in the crucible. At least one heating element in the crystal growth apparatus controls the melting in order to achieve the desired ingot growth as described above. The seeds that are placed in the bottom of the crucible may contain one or more seeds formed from at least one surface piece which may be obtained from any one of the above process.

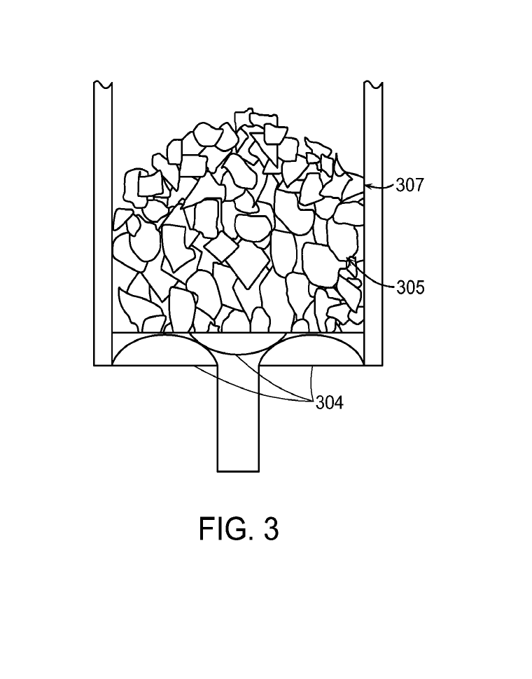

In the exemplary embodiment of the present invention, these surface pieces may additionally be cropped or left un-cropped depending upon how one or more seeds are to be disposed in the bottom of a crucible. More specifically, in the exemplary embodiment of the present invention, as can be seen from FIGS. 3-7, the one or more seeds may be placed in the bottom of the crucible in a variety of orientations. As stated above, the particular orientation used depends upon how and if the residual pieces were cropped after slicing the surface pieces from the boule.

For example, when the residual pieces are not cropped, as is shown in FIG. 3, a plurality of seeds 304 may be placed in the bottom of crucible 309 in an alternating pattern in which one seed has a curved surface facing in one direction while the neighboring or adjacent seeds have curved surfaces facing the opposite direction. In this illustrative embodiment of the present invention, each seed produced from the surface pieces are layered on the bottom of the crucible 309 so that the neighboring seed is rotated 180 degrees in relation to its neighboring seed (i.e., flipped/alternating). As discussed above, both the curved surface and the flat surface have the same crystal orientation, such as the <100> silicon crystal orientation. Placing these seeds in such an alternating pattern insures that the seeds remain in their correct positions once the feedstock is loaded into the crucible. Additional cropping to form flat surfaces is not needed. Furthermore in this exemplary embodiment, one or more gaps between neighboring seeds may in some embodiments be fused together with liquid silicon to further maintain a <100> crystal silicon orientation.

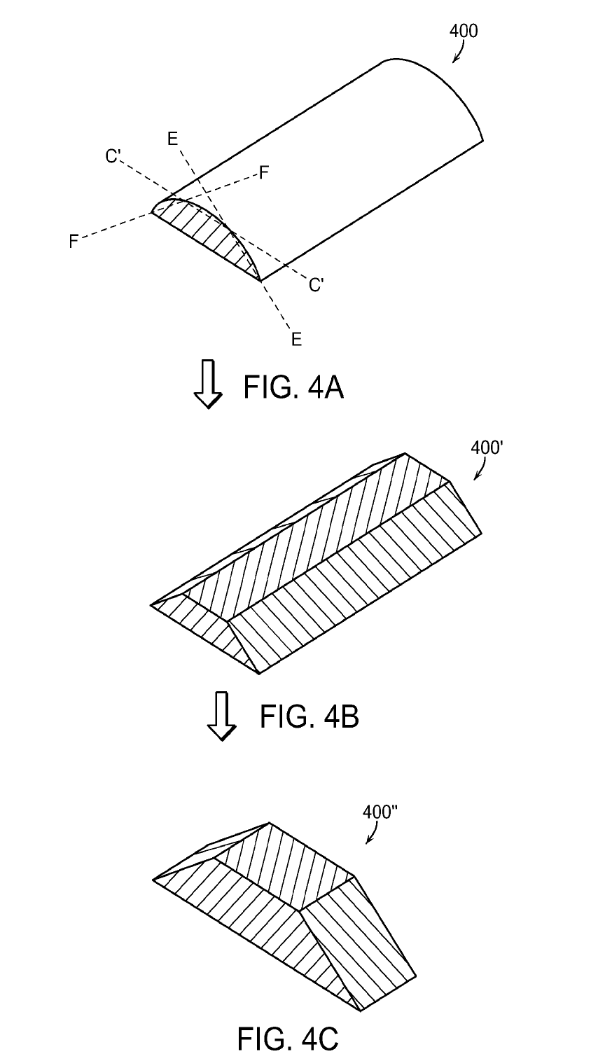

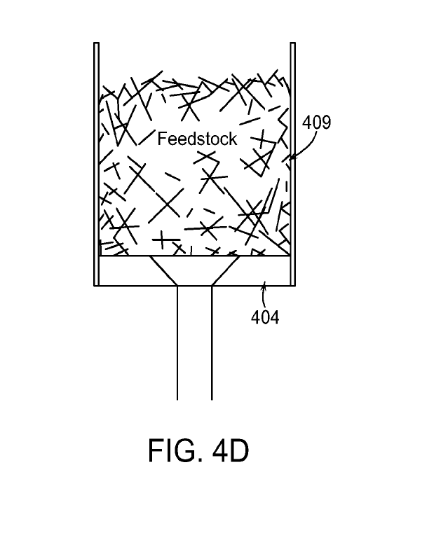

The cross section of a surface piece may also be cropped to provide a trapezoidal cross sectional shape, which can also be placed in a crucible using this alternating pattern, as is illustrated in FIG. 4D. In this embodiment, as can be seen from FIG. 4A, the sides of surface piece 400 is cut/cropped at about 45 degree opposing angles (i.e., along lines E-E and F-F) and a top section is further sliced/cropped off of the top of the surface piece to form a plank 400′ (FIG. 4B). A “plank” is defined as a substantially three dimensional rectangular or square structure having a length significantly greater than its width and height. Additionally, the plank 400′ may be sectioned into one or more smaller pieces 400″ that may be used as seeds, as shown in FIG. 4C. In some embodiments, in order for seeds to be effective in the silicon growth process, each seed should have a thickness T between about 5-35 mm. Therefore, depending on the thickness of the surface piece, the surface piece may, in some applications, be cropped to form a seed having a thickness T between 5-35 mm, preferably 10-25 mm and more preferably 10-20 mm. Alternatively, seeds may be stacked in order to achieve the desired thickness. The size of the seed can vary depending on, for example, the desired size of the final ingot (which is related to the size of the crucible) as well as the number of seeds to be used. Preferably, the seeds range in size from about 10 cm to about 85 cm along any edge. The resulting seeds may then be disposed in a bottom of a crucible 409 in an alternating pattern 404.

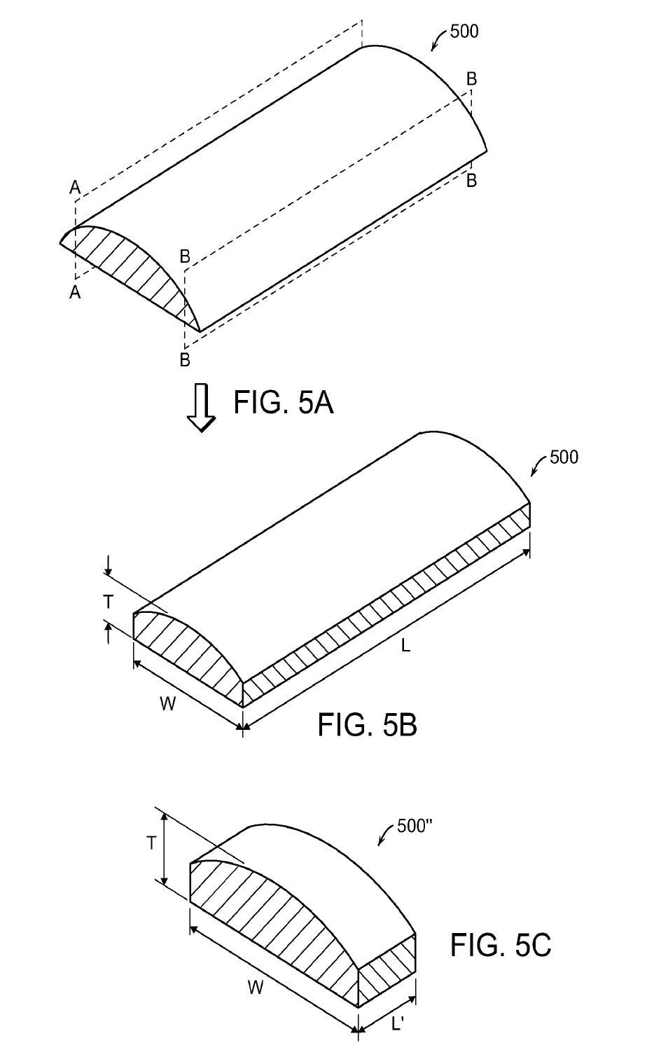

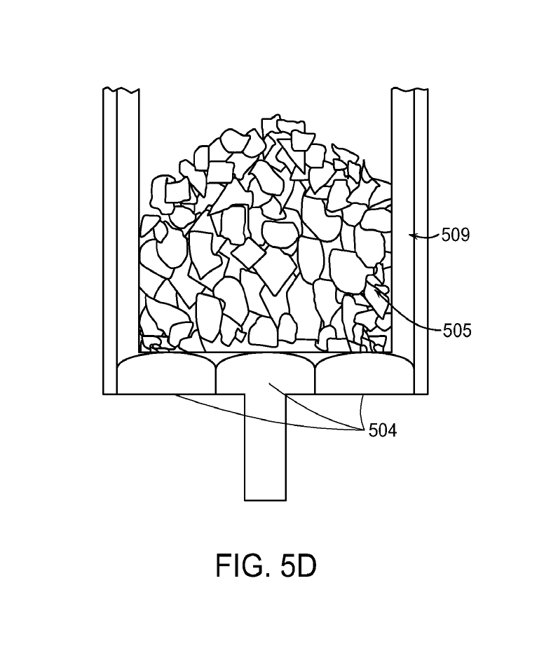

Alternatively, as illustrated in FIGS. 5A-D, surface piece 500 may also be cropped/cut along lines A-A and B-B as shown in FIG. 5A. In this embodiment, a first cut and a second cut may be made along the “corners” of a surface piece along lines A-A and B-B to form one or more seeds that has five flat surfaces and one curved surface, as is shown in FIGS. 5B. The resulting seed, in FIG. 5B, may be referred to as a “plank” 500′ with a thickness T, a width W and a length L. A plank in this instance may have a length that is equal to the length of the boule (sectioned or not) from which the surface pieces are obtained. Although not necessarily required, the boule may also be sectioned into smaller pieces prior to a surface piece being sliced from that portion of the boule. Furthermore, like in FIG. 4C, the plank 500′ may again be sliced into a plurality of seeds 500″ with a desired size and thickness. Seeds having the cross sectional shape as described in FIGS. 5A-C above may then be disposed in a crucible 509 in a non-alternating cross-sectional pattern 504 so that the side cut along lines A-A abuts the side cut along B-B of a neighboring seed as shown in FIG. 5D.

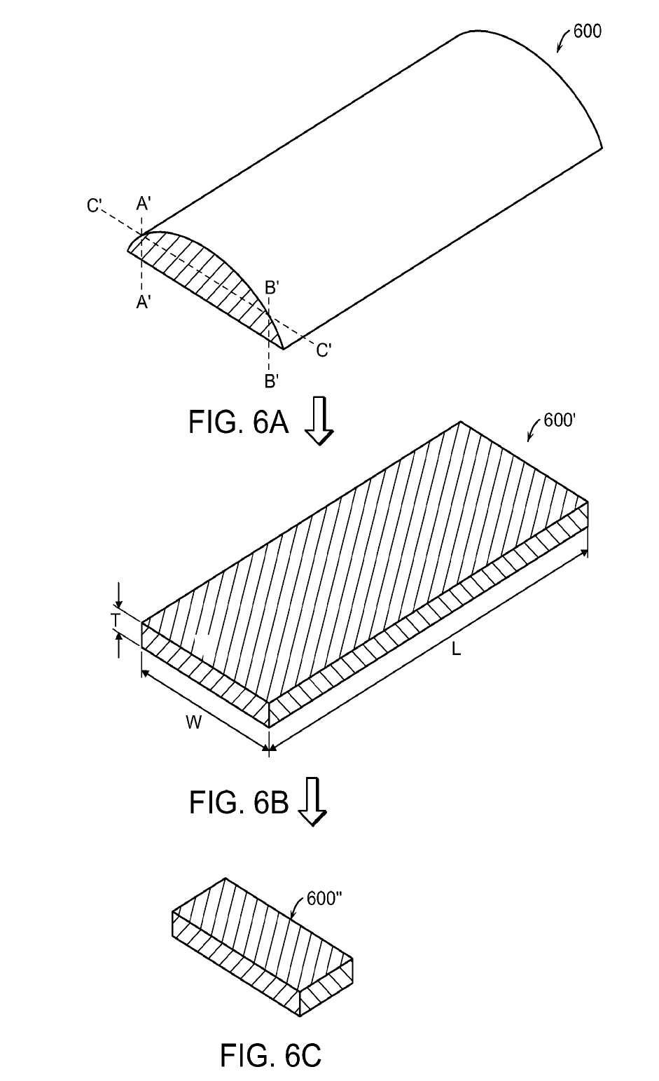

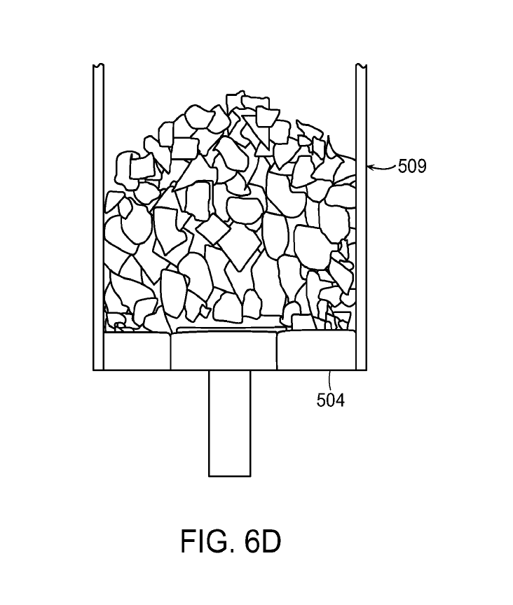

Furthermore, as shown in FIGS. 6A-D, a surface piece 600 alternatively may be cropped to form a rectangular shaped seed or seeds. For example, as shown in FIGS. 6A, a first cut, a second cut and a third cut are made along lines A′-A′, B′-B′ and C′-C′ of a surface piece. As a result, a seed having six flat surfaces and no curved surfaces is formed. The resulting seed, in FIG. 6B, may be referred to as a plank 600′ with a thickness T′, a width W and a length L as well. As can be seen from FIG. 6B, the width W and the L are substantially the same as the width W and length L of plank 500′ (FIG. 5B). In addition, like in the embodiment described in FIG. 5C, the plank 600′ in FIG. 6B may be sliced into a plurality of seeds 600″ with a desired size and thickness Seeds having the cross sectional shape as described in FIGS. 6A-C above may then be disposed in a crucible 609 in a non-alternating cross sectional pattern 604 so that the side cut along lines A′-A′ abuts the side cut along B′-B′ of a neighboring seed as shown in FIG. 6D.

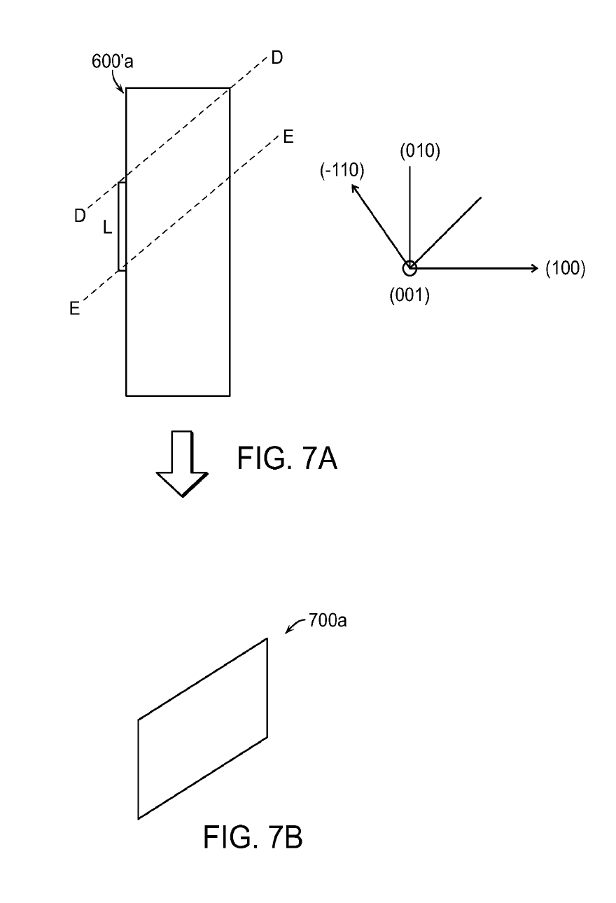

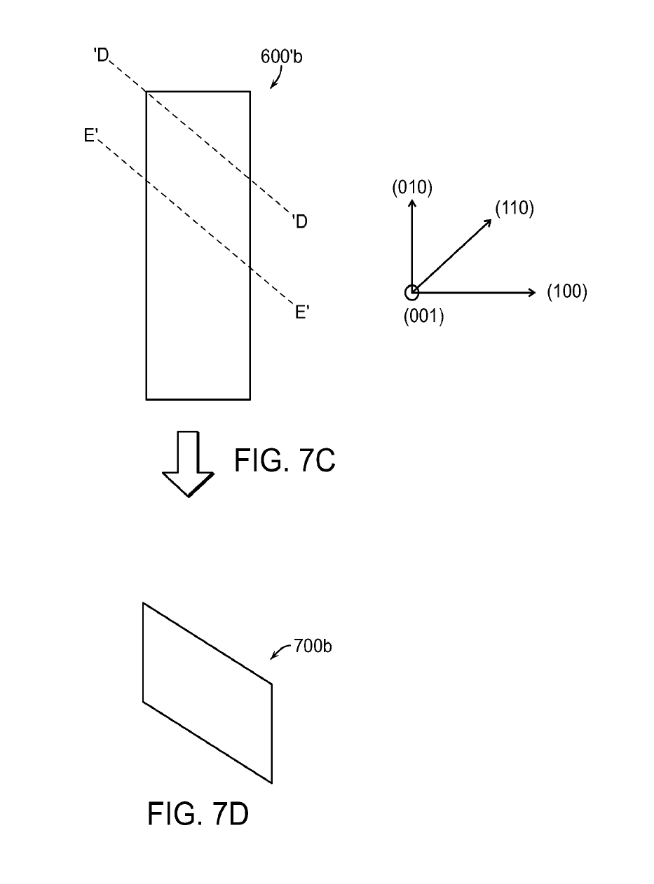

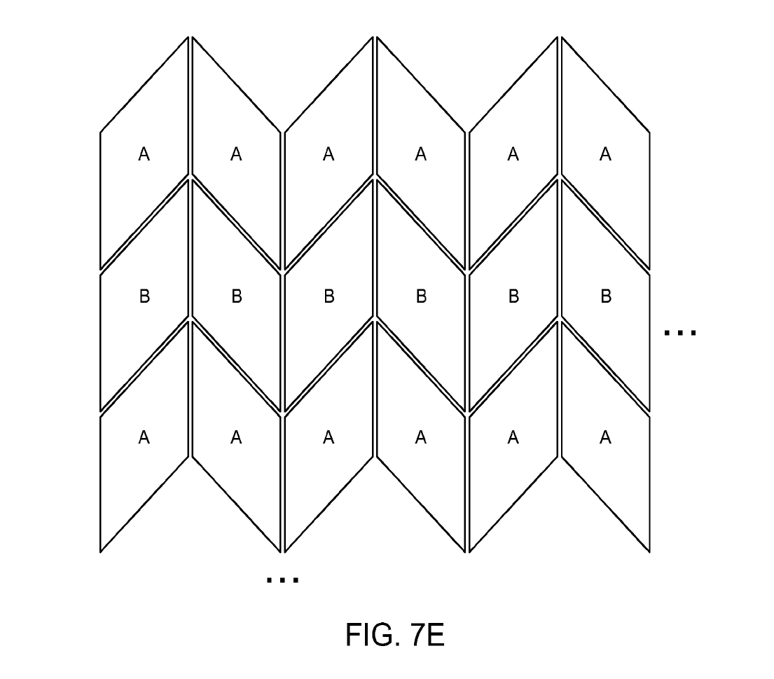

As stated above, the planks 600′ may be sliced into a plurality of seeds. However, how these seeds are sliced/cut may also affect properties of the boundary formed between adjacent seeds, thereby affecting the properties of the crystal ingot grown. FIGS. 7A-D provide a preferable technique for slicing the planks produced from the surface pieces which prevents or reduces sub-grain boundaries from forming between the neighboring seeds. More specifically, planks may be cut into at least one diamond shaped seed by slicing the plank at a plurality of predetermined angles.

In particular, as shown in FIG. 7A, a first cut D-D in a first plank 600′a may be made at about a 45 degree angle relative to an axis associated with the length the plank in the <110> direction. A second cut may then be made at about a 45 degree angle relative to the axis associated with the length of plank 600′a in the <110> direction at a predetermined length L away from the first cut. As a result of the first cut and the second cut, at least one diamond shaped seed 700a is formed (FIG. 7B).

In addition, as shown in FIG. 7C, a first cut D′-D′ in a second plank 600′b may be made at about a 45 degree angle relative to an axis associated with the length of the plank in the <−110> direction. A second cut may then be made at about a 45 degree angle relative to the axis associated with the length of the plank 600′b in the <−110> direction at a predetermined length L away from the first cut. As a result of the first cut and the second cut, at least one diamond shaped seed 700b may be formed (FIG. 7D).

The above process may be iterated a number of times until the desired number of diamond shaped seeds are produced. The resulting diamond shaped seeds in this exemplary embodiment of the present invention make up a first group of diamond shaped seeds (e.g., 700a) having at least one side surface with a <110> orientation and at least one side surface with a <100> orientation, and a second group of diamond shaped seeds (e.g., 700b) having orientations that mirror the first group.

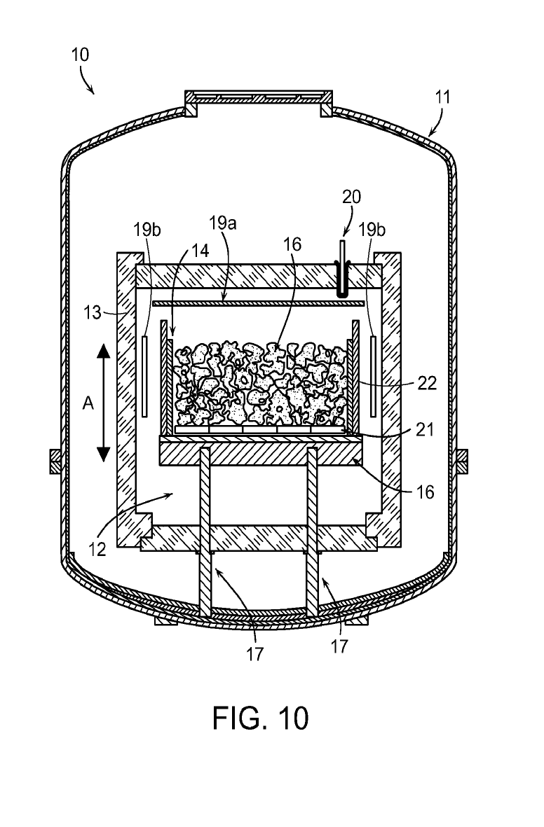

As shown in FIG. 7E, the first and second groups of diamond shaped seeds may be laid out in the bottom of a crucible to have the at least one side with a <100> orientation in the first group in contact with the at least one side with a <110> orientation in the second group of seeds. Placed in this way, sub-grain boundaries, which may initiate between two neighboring seeds in the conventional orientations and seeds placements as an ingot is grown in the crystal growth apparatus (such as the one shown in FIG. 10 and discussed further below) can be prevented.

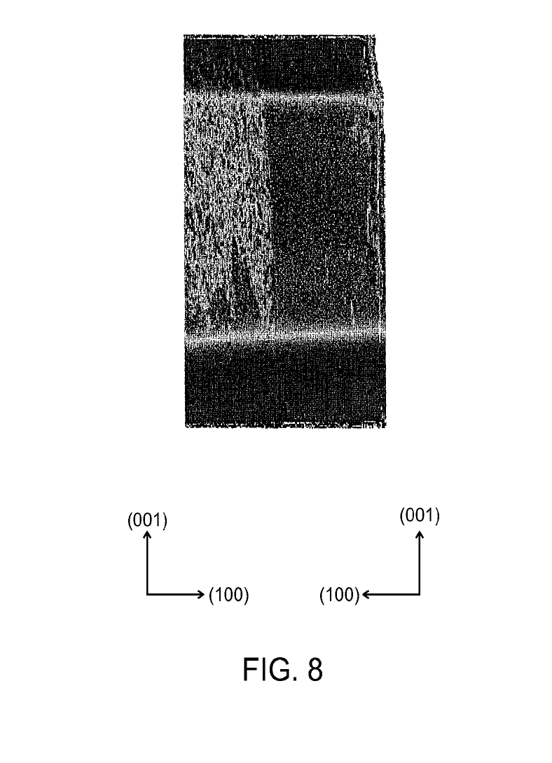

Sub-grains may also initiate from inclusions of silicon carbide and nitride. As the ingot grows, these inclusion induced sub-grains can invade an entire volume of the grown ingot. These defects have a significant impact on the efficiency of each solar cell produced from the resulting ingot. However, as can be seen from the minority carrier lifetime scan of a brick face of FIG. 8, when the above diamond shaped seeds are utilized, inclusion nucleated sub-grains are often unable to grow across a boundary. That is, in the exemplary embodiment of the present invention, the boundary itself provides protection against sub-grain multiplication and invasion.

It should be noted, however, that the above orientations are merely exemplary and other orientations using the above described diamond shaped seeds and rectangular seeds formed from the surface pieces of squaring a boule of silicon may be used without departing from the present invention.

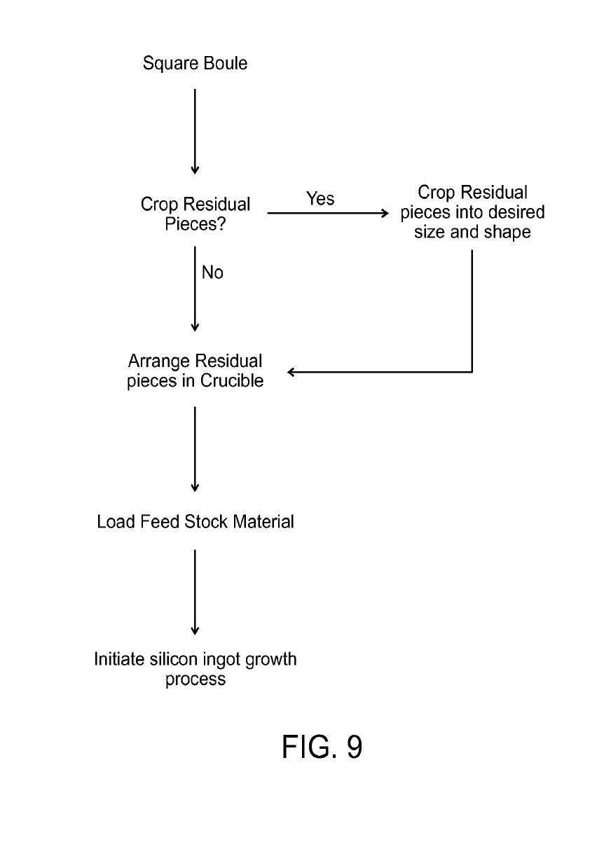

Using the above techniques, FIG. 9 depicts a flow chart illustrating a method manufacturing seeds for use in a crystal growth apparatus that reduces the overall cost of producing a silicon ingot by reducing the cost of the seeds used in growing the ingot and prevents or reduces sub-grains from forming between two seeds during silicon ingot growth. More specifically, a boule is squared by a squaring device in relation to a plurality of nodes at a particular orientation to create a brick from the boule in Step 902. As discussed above, a plurality of surface pieces result from squaring the boule. Next, a determination is made as to whether seeds are to be cropped or not (Step 904). If the seeds are to be cropped, a cropping device is utilized to crop each of the plurality of surface pieces to form at least one seed having a specific length, width and thickness from each of the plurality of surface pieces (Step 906). Multiple seeds can be formed from each surface piece, and the resulting seeds can be further washed, etched to remove metal contamination using one or more chemicals, and cleaned using distilled water to prepare them for use.

The seeds are arranged in the bottom of the crucible (Step 908), and feedstock material is loaded thereon (Step 910). If the seeds are not to be cropped, the at least one seed formed from a surface piece proceeds to Steps 908 and 910. Finally, the feedstock material is melted, without substantial melting of the seeds, and the melt is then solidified to form the silicon ingot (Step 912).

Furthermore, in a system for performing the above method, a squaring device, such as first ban saw or wire saw mounted with specific blade for squaring, may be used for squaring the boule. The squaring process in the exemplary embodiments of the present invention may be automated or manually driven depending up on the process being used. Likewise, any known cropping mechanism, such as a second band saw or wire saw mounted with a specific blade for cropping, may be used in the exemplary embodiment of the present invention to crop and slice the surface pieces into one or more seeds respectively. Furthermore, the first and second cutting devices may each include a plurality of saws that are each able to be configured to cut or slice the material at a preconfigured angle. Accordingly, the above described embodiments of the present invention are not limited thereto.

Advantageously, by utilizing these surface pieces the overall cost of producing a single silicon ingot of silicon can be reduced from, for example, $4000/ingot to $400/ingot. Furthermore, by specifically cropping, arranging and orientating the seeds formed from the surface pieces in the crucible as described above, sub-grain boundaries between two neighboring seeds can be greatly reduced if not prevented entirely.

The seeds produced by the above method may be utilized in a crystal growth apparatus, such as a directional solidification furnace, to form an ingot having a targeted crystal orientation. For example, as shown in FIG. 10, crucible 14 is contained within crucible box 15 and positioned on top of crucible block 16 that is raised on pedestal supports 17 within hot zone 12, which is surrounded by insulation 13 that can be moved vertically in direction A. Crucible 14 of crystal growth apparatus 10 comprises feedstock material 18 and a plurality of seeds 19. Seeds 19, which can be any of those described above, are arranged along the bottom of crucible 14 and substantially fully cover the entire bottom, with edges of one seed abutting an edge of at least one neighboring seed. While this illustratively shows monocrystalline seeds 19 tiled to fill the bottom of crucible 14 from edge to edge and corner to corner, as a practical matter, crucibles typically have some curvature in the corners and edges due to their method of preparation, and it may not be possible to tile the seeds beyond the curvature while still having the seeds lie flat along the crucible bottom. Feedstock material 18 can be provided around and on top of seeds 19.

A silicon ingot can be prepared using this crystal growth apparatus by heating and melting the feedstock material, using top heater 20a and side heaters 20b, monitored using thermocouple 21 preferably without substantially melting the seeds (although some partially seed melt back may be possible, especially for embodiments in which the seeds have a curved upper surface), and removing heat from the crucible to form the silicon ingot. If the seeds are placed in the crucible all having the same orientation, the resulting ingot would be a monocrystalline ingot (having the same crystal orientation throughout). If the seed are arranged to have alternating patterns of crystal orientations, then, while the portion of the ingot above the seed would be monocrystalline, the ingot as a whole would be a geometrically-ordered multicrystalline ingot (having multiple regions of different monocrystalline materials in an defined or ordered pattern).

Although preferred embodiments of the invention have been described using specific terms, such description is for illustrative purposes only, and it is to be understood that changes and variations may be made without departing from the spirit or scope of the following claims.

1. A method for manufacturing a seed for use in a silicon ingot growth process, the method comprising:
slicing, by a first cutting device, one or more surface pieces from a silicon boule in relation to a plurality of nodes at a particular orientation; and
forming the one or more surface pieces into one or more seeds having a specific length, width and thickness usable in a silicon ingot growth process.

2. The method of claim 1, further comprising:
cropping one or more of the surface pieces along predetermined cut lines prior to forming the one or more seeds.

3. The method of claim 1, wherein the one or more surface pieces are residual pieces formed as a result of squaring the silicon boule in relation to the plurality of nodes at a particular orientation to form a silicon brick.

4. The method of claim 3, wherein four residual pieces are formed as a result of squaring the silicon boule and wherein the brick has a pseudo square cross-sectional shape with a <100> orientation on each side surface.

5. The method of claim 1, wherein one or more surface pieces are cut, by a second cutting device, to form a first surface and a second surface of the surface piece, and as a result the cut surface piece has five flat surfaces and one curved surface.

6. The method of claim 1, wherein one or more surface pieces are cropped lengthwise to form two flat vertical side surfaces.

7. The method of claim 6, wherein one or more surface pieces are further cropped to form a flat horizontal top surface.

8. The method of claim 5, wherein the second cutting device cuts a first surface, a second surface, and a third surface of the surface piece, and as a result the cut surface piece has six flat surfaces.

9-14. (canceled)

15. The method of claim 1, wherein:
the silicon boule has an axis of growth in a <100> direction.

16. The method of claim 1, wherein:
a vector drawn normal from the axis of growth through any node is a <110> direction.

17. The method of claim 1, wherein the seeds are formed having a diamond shape.

18. The method of claim 17, wherein the one or more surface pieces are cropped into a plank, and wherein a first cut is made by a second cutting device in the plank at about a 45 degree angle relative to an axis associated with the length the plank, and wherein a second cut is made by the cutting device at about a 45 degree angle relative to the axis associated with the length of the plank parallel with the first cut and at a predetermined length away from the first cut, wherein the first cut and the second cut form the diamond shaped seed.

19. The method of claim 18, wherein a first group of diamond shaped seeds have at least one side surface with a <110> orientation and at least one side surface with a <100> orientation.

20. The method of claim 19, wherein a second group of diamond shaped seeds have orientations that minor the first group.

21-23. (canceled)

24. A method for growing a silicon ingot utilizing at least one seed manufactured by claim 1, the method comprising:
providing a crystal growth apparatus configured to promote ingot growth by directional solidification;
placing a plurality of seeds and a feedstock material in a crucible in the crystal growth apparatus;
heating and melting the feedstock material contained in the crucible, without substantially melting the seeds; and
removing heat from the crucible to form the silicon ingot.

25. The method of claim 24, wherein a first and second group of diamond shaped seeds are placed in the crucible to have a side surface with a <100> orientation in the first group in contact with a side surface with a <110> orientation in the second group.

26. The method of claim 24, wherein the plurality of seeds are stacked on top of each other in the crucible.

27. The method of claim 24, wherein the plurality of seeds have curved surfaces and are placed in the crucible in an alternating pattern of curved and flat surfaces.

28. The method of claim 27, further comprising fusing one or more gaps between neighboring seeds with liquid silicon to maintain a <100> crystal silicon orientation.

29. (canceled)

30. A system for manufacturing a seed for use in a silicon ingot growth process, the system comprising:
a first cutting device configured to slice one or more surface pieces from a silicon boule in relation to a plurality of nodes at a particular orientation; and
a second cutting device configured to form the one or more surface pieces into one or more seeds having a specific length, width and thickness usable in a silicon ingot growth process.

31-58. (canceled)
